(19) United States
(12) Patent Application Publication
(10) Pub. No.: US 2024/0307988 A1
(43) Pub. Date: Sep. 19, 2024

(54) HYBRID ELECTROCHEMICAL AND ABRASIVE FLUID POLISHING

(71) Applicant: University College Dublin, National University of Ireland, Dublin, Dublin (IE)

(72) Inventors: Fengzhou Fang, Dublin 14 (IE); Mingyue Shen, Shijiazhuang City (CN)

(21) Appl. No.: 18/566,198

(22) PCT Filed: Jun. 1, 2022
(86) PCT No.: PCT/EP2022/064975

§ 371 Date: Dec. 1, 2023

(30) Foreign Application Priority Data
Jun. 1, 2021 (GB) 2107777.1

(51) Int. Cl. B23H 5/08; C09G 1/02; C25F 3/16; C25F 7/00

(52) U.S. Cl. CPC B23H 5/08; C09G 1/02; C25F 3/16; C25F 7/00

(57) ABSTRACT

A method of performing hybrid electrochemical and abrasive fluid polishing is provided. The method comprised disposing (202) a workpiece to be polished and a cathode in a flow of polishing fluid, wherein the polishing fluid comprises at least one electrolyte and at least one abrasive medium. The method further comprises connecting (204) the workpiece and the cathode to an electrical power supply. An apparatus (100) is also provided for hybrid electrochemical and abrasive fluid polishing. The apparatus comprises a vessel (102) comprising an inlet (103a) and an outlet (103b) to allow a flow of fluid through the vessel. The apparatus further comprises one or more mounts (104) configured to hold a workpiece (108) to be polished in the vessel between the inlet and the outlet. The apparatus also comprises one or more connectors (106) configured to connect the workpiece and a cathode (110) to an electrical power supply.

### FIELD

The present invention relates to a method of, and apparatus for, hybrid polishing, and in particular but not exclusively to hybrid electrochemical and abrasive fluid polishing.

### BACKGROUND

Products and parts having internal structures such as conformal channels and lattice structures are widely used across various industries, in particular the automotive, aerospace, medical and mould industries.

Compared with traditional manufacturing techniques, additive manufacturing approaches such as selective laser melting (SLM) are more attractive for manufacturing parts having such internal structures. Such approaches typically have a higher accuracy and are not restricted by geometric limitations in preparing parts having complex internal structures.

Despite those advantages, additive manufacturing approaches such as SLM still present a limitation in terms of poor surface quality. Surface finish is typically an important factor relating to the application of a part, influencing multiple functional characteristics including but not limited to biological response, mechanical properties, fluid dynamics and heat transfer.

The surface quality of parts produced by additive manufacturing approaches such as SLM is usually inferior because of various factors such as adhesion of partially melted particles, balling effects and staircase effects introduced, for example, during laser processing.

Traditional post-processing techniques, such as milling and grinding, are widely used for improving surface quality of outer surfaces on parts produced by additive manufacturing. However, such conventional methods are restricted by a physical size of the tools used, meaning it can be difficult to achieve effective surface improvement for additively manufactured parts having internal structures. Those post-processing techniques are therefore not suitable for surface improvement of internal structures of additively manufactured parts.

The present invention has been devised with the foregoing in mind.

### SUMMARY

According to a first aspect, there is provided a method of performing hybrid polishing. The method may comprise hybrid electrochemical and abrasive fluid polishing. Hybrid polishing may comprise performing both electrochemical polishing and abrasive fluid polishing substantially simultaneously. The method may comprise disposing a workpiece to be polished and a cathode in a flow of polishing fluid. The polishing fluid may comprise at least one electrolyte. The polishing fluid may comprise at least one abrasive medium. The method may comprise connecting the workpiece and the cathode to a power supply.

Advantageously, such a hybrid electrochemical and abrasive fluid polishing approach may combine the benefits, and overcome or ameliorate at least some of the limitations, of the separate individual processes when performed alone.

Electrochemical polishing (electropolishing) has several disadvantages as a standalone process. Electropolishing has a limitation in polishing quality which means a rough initial surface will impede fast and effective polishing. For example, surface roughness (Ra) of SLM parts typically varies between approximately 4 μm and 20 μm. It is therefore not always appropriate to polish a raw surface by electropolishing directly. For internal structures having intricate geometries, it may also be difficult to achieve a uniform surface finish due to a limited accessibility of cathode tools. Existing cathode tools are typically suitable for flat workpieces of outer surfaces having a small curvature change, and are not able to be placed inside workpieces for electropolishing small-scale, intricate internal structures.

Similarly, abrasive fluid polishing alone has a number of limitations. Abrasive fluid polishing provides a low material removal rate and a low efficiency due to the low pressures that are typically used. Abrasive fluid polishing is also limited to a select number of materials having low hardness and low abrasive resistance (e.g., AlSi10Mg).

Incorporating abrasive fluid polishing in the hybrid process by including at least one abrasive medium in the polishing fluid may enable the hybrid process to be used on parts having a wider range of initial surface qualities (e.g., Ra) compared to electropolishing alone, including rough initial surfaces such as those produced by SLM. Incorporating abrasive fluid polishing in the hybrid process rather than abrasive fluid machining (which uses higher pressures than abrasive fluid polishing) may also address the limitations of electropolishing without introducing contamination or abrasive agglomeration issues typically experienced during abrasive flow machining.

Incorporating electropolishing in the hybrid process by including at least one electrolyte in the polishing fluid may enable the hybrid process to be used across a wider range of material compositions compared to abrasive fluid polishing alone. Electropolishing is independent of mechanical properties of the material composition. That may overcome the limitations of the mechanical approach of abrasive fluid polishing. That may also increase material removal rate and improve polishing efficiency.

Hybrid electrochemical and abrasive fluid polishing may therefore be suitable for a wide range of materials having a wide range of initial surface qualities. Hybrid electrochemical and abrasive fluid polishing may be particularly suitable for polishing parts having internal structures with rough surfaces, for example parts produced using additive manufacturing processes such as SLM. The hybrid process may be able to deal with rough initial surfaces of additively manufactured parts whilst easily accessing and acting upon any internal surfaces or structures of the parts.

The electrolyte may comprise an environmentally friendly electrolyte. The electrolyte may be or comprise a weak acid. That may reduce the environmental impact of the hybrid polishing process compared to conventional electropolishing or chemical polishing processes which typically use strong acids.

The electrolyte may be or comprise phosphoric acid. Phosphoric acid may enable the dissolution of metal elements and oxide films on alloy surfaces. The viscosity of phosphoric acid may also enable or contribute to the formation of a viscous layer at the surface of a workpiece during the hybrid polishing process. That may enable stable polishing during the hybrid polishing process, which may result in a bright polished surface. The phosphoric acid in the electrolyte may be 85%+ aqueous solution of phosphoric acid, although it will be appreciated that a final concentration of phosphoric acid in the electrolyte will depend on a proportion of phosphoric acid (e.g., by volume) present in the electrolyte. The proportion of phosphoric acid present in the electrolyte may be varied depending upon at least one of a material composition and an initial surface quality of a part to be polished. The electrolyte may therefore be tailored to or optimized for polishing specific materials and/or parts manufactured using specific techniques. Additionally or alternatively, other weak acids may be used such as citric acid or acetic acid (for example, glacial acetic acid). The citric acid or acetic acid may be substantially pure citric acid or acetic acid (for example, having an initial concentration of 99%+). The electrolyte may comprise a mixture of different weak acids, for example phosphoric acid with one or more other weak acids. The one or more other weak acids may be included as additives. The mixture may comprise up to substantially 70% of the one or more other weak acids.

The electrolyte may be or comprise a mixture of a weak acid and a viscous component. The viscous component may suppress over-etching by forming or contributing to (for example, increasing a thickness of) a viscous layer at the surface of a workpiece during the hybrid polishing process. The viscous component may be or comprise glycerine. The hydroxides present in glycerine may also contribute to suppressing over etching by increasing a thickness of the viscous layer at the surface of the workpiece during the hybrid polishing process. Additionally or alternatively, the viscous component may be or comprise one or more of glycol, methanol, butanol, isopropanol and ethanol. The viscous component may be a substantially pure viscous component (for example, having an initial concentration of 99%+).

The electrolyte may comprise between substantially 20% and substantially 80% weak acid by volume, and optionally may comprise between substantially 30% and substantially 60% weak acid by volume. The electrolyte may additionally comprise between substantially 5% and substantially 50% viscous component by volume, and optionally may comprise between substantially 10% and substantially 30% viscous component by volume. The electrolyte may further comprise water, and optionally may comprise deionised water. The addition of water may increase a current density during the hybrid polishing process which may in turn increase a material removal rate during the hybrid polishing process. That may make the electrolyte particularly suitable for parts having a rough initial surface (e.g., poor surface quality), such as additively manufactured parts. Such compositions may be particularly suitable for additively manufactured parts formed from steel, such as parts manufactured from 316L stainless steel using SLM. However, the composition of the electrolyte may be varied depending upon at least one of a material composition and an initial surface quality of a part to be polished.

The electrolyte may be, comprise or consist of substantially 30% weak acid (e.g., phosphoric acid) by volume, substantially 10% viscous component (e.g., glycerine, glycol or methanol) by volume and substantially 60% deionised water by volume. Alternatively, the electrolyte may be, comprise or consist of substantially 45% weak acid (e.g., phosphoric acid) by volume, substantially 15% viscous component (e.g., glycerine, glycol or methanol) by volume and substantially 40% deionised water by volume. Alternatively, the electrolyte may be, comprise or consist of substantially 60% weak acid (e.g., phosphoric acid) by volume, substantially 20% viscous component (e.g., glycerine, glycol or methanol) by volume and substantially 20% deionised water by volume.

The at least one abrasive medium may comprise at least one of ceramic particles and plastic particles. The polishing fluid may comprise up to substantially 50% by mass of the at least one abrasive medium. The at least one abrasive medium may be or comprise SiC particles. The particles may be up to 300 μm in size (for example, diameter). Additionally or alternatively, the at least one abrasive medium may be or comprise at least one of B₄C particles, BN particles (such as cubic BN particles) and Al₂O₃ particles. At least one of a type, size and mass ratio of the at least one abrasive medium may be varied depending on a material and/or an initial surface quality of a part to be polished.

The method may comprise locating or supporting the workpiece and the cathode in a vessel. The vessel may comprise an inlet and an outlet to allow the polishing fluid to flow through the vessel. The vessel may be or comprise a hollow chamber. The hollow chamber may substantially enclose a space between the inlet and the outlet. The hollow chamber may enable the polishing fluid to be pressurized. A pressure of the polishing fluid may be varied during the hybrid polishing process.

The method may further comprise disposing the workpiece in a flow of cleaning fluid. The cleaning fluid may be or comprise deionized water. The cleaning fluid may clean the part being polished, for example by removing remnant polishing fluid. The method may comprise disposing the workpiece in the flow of cleaning fluid after, and separately from, disposing the workpiece in the flow of polishing fluid. Locating the workpiece in a vessel may allow the part to easily be both polished and cleaned using a single system or apparatus (for example, without moving the part).

The method may comprise monitoring one or more polishing parameters. The one or more polishing parameters may be or comprise one or more of a polishing fluid pressure, a polishing fluid flow rate, a polishing fluid temperature, a current and/or a current density, and an electric potential.

The method may comprise controlling or adjusting at least one of the one or more polishing parameters. The controlling or adjusting of the one or more polishing parameters may be based on monitoring of the one or more polishing parameters. The one or more polishing parameters may each influence the final polishing effect, as may the interaction of multiple polishing parameters. For example, a temperature of the polishing fluid may influence a current or current density. In general, increasing the polishing fluid temperature may increase the current or current density. An appropriate current is required to achieve a sufficient material removal rate. However, if the current is too high that may result in a material removal rate that is too high, causing excess material to be removed from a surface of the workpiece (material waste) and over-etching. Thus, two or more of the polishing parameters may coordinate with one another, and be controlled or adjusted, in order to achieve a desired polishing effect and polishing efficiency.

According to a second aspect, there is provided an apparatus for hybrid electrochemical and abrasive fluid polishing. The apparatus may comprise a vessel. The vessel may comprise an inlet and an outlet to allow a flow of fluid through the vessel. The apparatus may comprise one or more mounts. The mounts may be configured to hold a workpiece to be polished in the vessel between the inlet and the outlet. The apparatus may also comprise one or more connectors configured to connect the workpiece and the cathode to a power supply.

The apparatus may enable hybrid electrochemical and abrasive fluid polishing to be performed. Hybrid electrochemical and abrasive fluid polishing may be suitable for a wide range of materials having a wide range of initial surface qualities. Hybrid electrochemical and abrasive fluid polishing may be particularly suitable for polishing parts having internal structures with rough surfaces, for example parts produced using additive manufacturing processes such as SLM. The hybrid process may be able to deal with rough initial surfaces of additively manufactured parts whilst easily accessing and acting upon any internal surfaces or structures of the parts.

The vessel may comprise a hollow chamber. The hollow chamber may substantially enclose a space between the inlet and the outlet. That may enable a fluid pressure in the vessel to be adjusted and/or controlled as the fluid flows through the vessel. The chamber may comprise a bore or conduit between the inlet and the outlet. That may provide a substantially consistent, predictable flow of fluid through the vessel, and across the workpiece and the cathode.

The vessel may comprise a plurality of releasably attachable vessel portions. That may allow modular replacement of different vessel portions. Each vessel portion may be replaced independently of the other vessel portions. For example, one of the vessel portions may degrade or fail before the other vessel portions due to a flow of fluid through the vessel.

The vessel may comprise a central portion and two end portions. Each end portion may be configured to attach to a separate end of the central portion. Alternatively, the vessel may comprise any suitable number of vessel portions, for example, depending upon a length of the vessel.

Each vessel portion may comprise at least one mating surface. Each mating surface may be configured to engage with a corresponding mating surface of another vessel portion. One or more of the mating surfaces may extend outward or away from an internal surface of the vessel (for example, over which fluid flows). That may enable the vessel portions to function substantially separately from the internal surface of the vessel.

Corresponding mating surfaces may comprise complementary engagement features. One or more of the mating surfaces may comprise at least one raised area. One or more of the corresponding mating surfaces may comprise at least one recessed area. The complementary engagement features may further secure the vessel portions to one another, for example by inhibiting or preventing rotation of the vessel portions relative to one another when attached. The complementary engagement features may also act to easily locate the vessel portions in a correct position relative to one another when attaching the vessel portion to one another.

One or more of the mounts may be configured to hold a cathode in the vessel between the inlet and the outlet.

The one or more mounts and/or the cathode may be configured to be secured between adjacent vessel portions, for example between mating surfaces of adjacent vessel portions. That may inhibit or prevent movement of the mounts during use. That may enable the mounts to hold the workpiece and/or the cathode in a substantially stable position when fluid is flowing through the vessel. That may also ensure that the workpiece and the cathode are held at a substantially fixed distance from one another in the vessel, which may enable a polishing process to be more easily controlled. That may also enable the workpiece and/or the cathode to be easily placed or secured within the vessel if the vessel is small, for example if the vessel comprises a chamber that is too small for an operator to manually reach inside).

The one or more mounts and/or the cathode may be configured to be secured between complementary engagement features on the mating surfaces. That may enable the mounts and/or the cathode to be secured between the vessel portions whilst still enabling the mating surfaces to be brought into contact one another, for example to form a substantially fluid-tight seal between the vessel portions.

The apparatus may comprise a first mount configured to hold the workpiece and a second mount configured to hold the cathode. The first mount and the second mount may be configured to be secured between the mating surfaces of different vessel portions, for example different pairs of vessel portions.

The one or more mounts may be or comprise a conductive material. The one or more connectors may be configured to connect the workpiece and the cathode to a power supply via the one or more mounts.

The one or more connectors may be located on or extend through a mating surface of a vessel portion. That may enable the connectors to be easily brought into contact with a mount and/or a cathode secured between the mating surfaces of the vessel portions, without the connectors physically entering the vessel and being exposed to potentially harsh environmental conditions during a polishing process. That may also reduce a number of potential leak points of the apparatus, by using a point of entry into the vessel for multiple purposes (for example, to form both a physical and an electrical connection to the workpiece and/or the cathode within the chamber).

The one or more connectors may be located on or extend through one or more engagement features on a mating surface. If the mounts and/or the cathode are secured between the complementary engagement features on corresponding mating surfaces, that may automatically ensure that the connectors are spatially positioned to form an electrical contact with the mount and/or the cathode when the vessel portions are attached to one another.

The vessel may be made from or comprise polyether ether ketone (PEEK). PEEK is a strong material capable of withstanding temperatures up to 260° C. PEEK is also an electrical insulator and has good resistance to a wide range of different chemicals. PEEK may therefore provide sufficient mechanical, thermal, electrical and chemical properties for a vessel for use in a hybrid electrochemical and abrasive fluid polishing process. Alternatively, the vessel may be made from or comprise one or more of acrylic, polytetrafluoroethylene, polyvinylidene difluoride or a fibre reinforced plastic.

According to a third aspect, there is provided a system for hybrid electrochemical and abrasive fluid polishing. The system may comprise the apparatus of the second aspect. The system may further comprise a device configured to provide or deliver a fluid (for example, a polishing fluid) to the apparatus. The system may also comprise a power supply configured to connect to a workpiece and a cathode in the apparatus.

According to a fourth aspect, there is provided a fluid for electrochemical processing. The fluid may be or comprise a mixture of a weak acid and a viscous component.

A weak acid may reduce the environmental impact of the hybrid polishing process compared to conventional electropolishing or chemical polishing processes which typically use strong acids. The viscous component may suppress over-etching by forming or contributing to (for example, increasing a thickness of) a viscous layer at the surface of a workpiece during electrochemical processing.

The weak acid may be or comprise phosphoric acid. Phosphoric acid may enable the dissolution of metal elements and oxide films on alloy surfaces. The viscosity of phosphoric acid may also enable or contribute to the formation of a viscous layer at the surface of a workpiece during the hybrid polishing process. That may enable stable polishing during the hybrid polishing process, which may result in a bright polished surface. The phosphoric acid in the electrolyte may be 85%+ aqueous solution of phosphoric acid, although it will be appreciated that a final concentration of phosphoric acid in the electrolyte will depend on a proportion of phosphoric acid (e.g., by volume) present in the electrolyte. The proportion of phosphoric acid present in the electrolyte may be varied depending upon at least one of a material composition and an initial surface quality of a part to be polished. The electrolyte may therefore be tailored to or optimized for polishing specific materials and/or parts manufactured using specific techniques. Additionally or alternatively, other weak acids may be used such as citric acid or acetic acid (for example, glacial acetic acid). The citric acid or acetic acid may be substantially pure citric acid or acetic acid (for example, having an initial concentration of 99%+). The electrolyte may comprise a mixture of different weak acids, for example phosphoric acid with one or more other weak acids. The one or more other weak acids may be included as additives. The mixture may comprise up to substantially 70% of the one or more other weak acids.

The viscous component may be or comprise glycerine. The hydroxides present in glycerine may also contribute to suppressing over etching by increasing a thickness of the viscous layer at the surface of the workpiece during the hybrid polishing process. Additionally or alternatively, the viscous component may be or comprise one or more of glycol, methanol, butanol, isopropanol and ethanol. The viscous component may be a substantially pure viscous component (for example, having an initial concentration of 99%+).

The fluid may comprise between substantially 20% and substantially 80% of a weak acid by volume, and optionally may comprise between substantially 30% and substantially 60% weak acid by volume. The fluid may comprise between substantially 5% and substantially 50% of a viscous component by volume, and optionally may comprise between substantially 10% and substantially 30% viscous component by volume. The remainder of the fluid may be or comprise water, such as deionized water. The addition of water may increase a current density during the hybrid polishing process which may in turn increase a material removal rate during the hybrid polishing process. That may make the fluid particularly suitable for polishing parts having a rough initial surface (e.g., poor surface quality), such as additively manufactured parts. Such fluids may be particularly suitable for additively manufactured parts formed from steel, such as parts manufactured from 316L stainless steel using SLM. However, the composition of the fluid may be varied depending upon at least one of a material composition and an initial surface quality of a part to be polished.

The fluid may further comprise at least one abrasive medium. The at least one abrasive medium may comprise at least one of ceramic particles and plastic particles. The polishing fluid may comprise up to 50% by mass of the at least one abrasive medium. The at least one abrasive medium may be or comprise SiC particles. The SiC particles may be up to 300 μm in size (for example, diameter). Additionally or alternatively, the at least one abrasive medium may be or comprise at least one of B₄C particles, BN particles (such as cubic BN particles) and Al₂O₃ particles. At least one of a type, size and mass ratio of the at least one abrasive medium may be varied depending on a material and/or an initial surface quality of a part to be polished. That may allow the fluid to be used for hybrid electrochemical and abrasive fluid polishing.

The method of the first aspect may be used with the apparatus of the second aspect, the system of the third aspect and/or may utilise the fluid of the fourth aspect.

The optional features from any aspect may be combined with the features of any other aspect, in any combination. For example, the method of the first aspect may comprise using at least one of the apparatus of the second aspect, the system of the third aspect and the fluid of the fourth aspect, and any one or more of the features described with reference to those aspects, and vice versa. The apparatus of the second aspect and the system of the third aspect may be configured to perform the method of the first aspect. Furthermore, the method of the first aspect may comprise any of the optional features described with reference to the apparatus of the second aspect, and vice versa. Features may be interchangeable between different aspects and embodiments, and may be removed from and/or added to different aspects and embodiments.

Features which are described in the context of separate aspects and embodiments of the invention may be used together and/or be interchangeable wherever possible. Similarly, where features are described in the context of a single embodiment for brevity, those features may also be provided separately or in any suitable sub-combination. Features described in connection with the method of the first aspect may have corresponding features definable with respect to the system of the second aspect and vice versa, and these embodiments are specifically envisaged.

### BRIEF DESCRIPTION OF DRAWINGS

The invention will now be described by way of example only with reference to the accompanying drawings in which:

FIG. 1 shows a schematic cross-section of an apparatus for hybrid electrochemical and abrasive fluid polishing in accordance with an embodiment of the invention; and

FIGS. 2A, 2B and 2C show a vessel of the apparatus shown in FIG. 1 in more detail;

FIGS. 3A, 3B and 3C show a mount of the apparatus shown in FIG. 1 in more detail;

FIGS. 4A and 4B show connectors of the apparatus shown in FIG. 1 in more detail;

FIGS. 5A, 5B and 5C show cathode tools in accordance with embodiments of the invention; and

FIG. 6 shows a method of hybrid electrochemical and abrasive fluid polishing in accordance with an embodiment of the invention;

FIG. 7 shows another method of hybrid electrochemical and abrasive fluid polishing in accordance with an embodiment of the invention; and

FIG. 8 shows a system for carrying out the hybrid electrochemical and abrasive fluid polishing method shown in FIG. 7, in accordance with an embodiment of the invention.

Like reference numerals and designations in the various drawings may indicate like elements.

### DETAILED DESCRIPTION

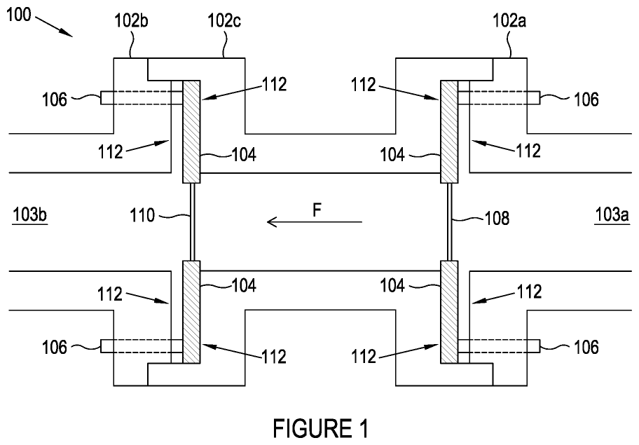

FIGS. 1 to 4 show an apparatus 100 for hybrid electrochemical and abrasive fluid polishing, in accordance with an embodiment of the invention. The apparatus 100 comprises a vessel 102. The vessel 102 comprises an inlet 103a and an outlet 103b to allow a flow of fluid through the vessel 102. The apparatus 100 also comprises one or more mounts 104. The mounts 104 are configured to secure or hold a workpiece 108 (e.g., a part to be polished) and/or a cathode 110 in the vessel 102, between the inlet 103a and the outlet 103b. The mounts 104 are therefore configured to hold the workpiece 108 and/or the cathode 110 in the fluid when the fluid is flowing through the vessel 102. The apparatus 100 further comprises one or more connectors 106. The connectors 106 are configured to connect the workpiece 108 and the cathode 110 to an electrical power supply.

FIG. 1 shows a schematic cross-section of the apparatus 100. In the embodiment shown, the vessel 102 comprises a substantially hollow chamber. The chamber substantially encloses the space between the inlet 103a and the outlet 103b of the vessel 102. That may enable fluid pressure in the vessel 102 to be adjusted and/or controlled as the fluid flows through the vessel 102 (depicted by the arrow labelled F in FIG. 1). Alternatively, the vessel 102 may have or comprise an open structure, for example an open-topped pipe or channel.

The inlet 103a, the outlet 103b and the internal space defined by the hollow chamber of the vessel 102 each comprise a cross-section of substantially the same shape and size. In the embodiment shown, the cross-sections of each of the inlet 103a, the outlet 103b and the chamber are substantially circular and substantially equal sizes. The chamber of the vessel 103 therefore defines a substantially continuous bore or conduit between the inlet 103a and the outlet 103b. That may provide a substantially consistent, predictable flow of fluid through the vessel 102 and across the workpiece 108 and the cathode 110. However, the sizes and shapes of the respective cross-sections of the inlet 103a, the outlet 103b and the chamber of the vessel 102 need not be the same as one another. For example, a size of the cross-section of the chamber may be larger than a size of the cross-section of the inlet 103a and the outlet 103b. The cross-section of the inlet 103a, the outlet 103b and the chamber may be any suitable shape, for example triangular, square, substantially polygonal etc.

The vessel 102 comprises a plurality of vessel portions. The plurality of vessel portions comprise end portions 102a, 102b and a central portion 102c, although any number of vessel portions may alternatively be used (for example, depending upon a length of the vessel 102). The vessel portions 102a-c are releasably attachable to one another to form the vessel 102. The end portions 102a, 102b are configured to attach to the respective ends of the central portion 102c. The inlet 103a and the outlet 103b are disposed on the respective end portions 102a, 102b. Each vessel portion 102a-c comprises a fluid aperture. The fluid apertures of each vessel portion 102a-c are configured to substantially align with one another when the vessel portions 102a-c are attached to one another, to form a path or channel for fluid to flow through the vessel 102 between the inlet 103a and the outlet 103b. That structure may allow modular replacement of different vessel portions 102a-c rather than replacement of the whole vessel 102. For example, if one of the vessel portions 102a-c degrades or fails before the other vessel portions 102a-c due to a flow of fluid through the vessel 102, that vessel portion may be replaced independently of the other vessel portions 102a-c. Alternatively, the vessel 102 may be or comprise a single or unitary structure.

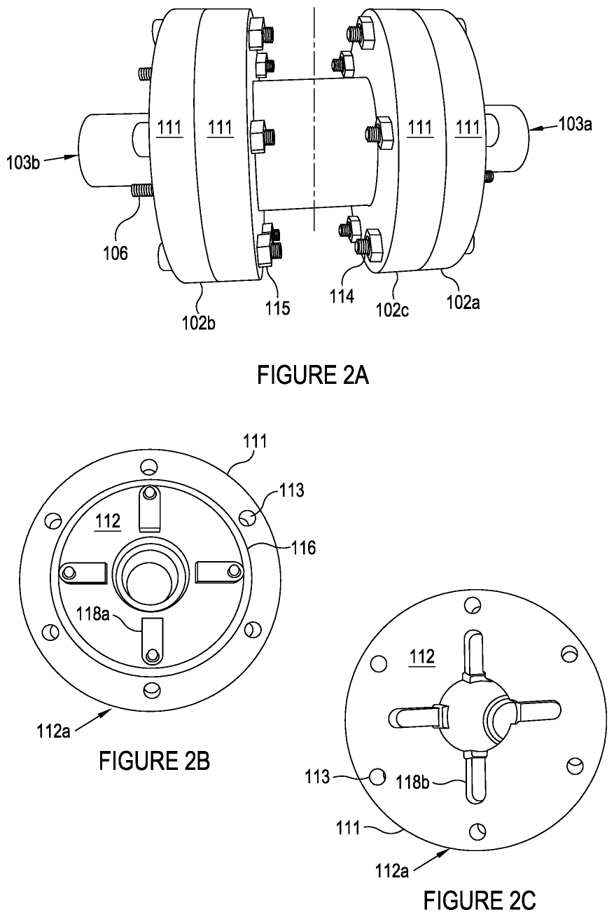

The vessel portions 102a-c each comprise at least one mating portion or flange 111 in the embodiment shown. The mating portion or flange 111 comprises a mating surface 112. The vessel portions 102a-c are configured to attach to one another via the mating portions 111, with the mating surfaces 112 being brought substantially into contact with one another. The mating surfaces 112 comprise a substantially annular region 112a extending radially outward from the fluid apertures passing through each vessel portion 102a-c, although the mating surfaces may have any suitable shape or form. Each mating portion 111 is configured to receive one or more fasteners to secure the vessel portions 102a-c to one another. In the embodiment shown, each mating portion 111 comprises a plurality of holes 113 each configured to receive a bolt 114, shown in more detail in FIGS. 2A-C. The bolt 114 is attached to a nut 115. The nut 115 is tightened onto the bolt 114 to clamp the mating surfaces 112 against one another. Alternatively, a different type of fastener such as one or more screws, or a clamp mechanism, may be used to secure the vessel portions 102a-c to one another. Alternatively, the vessel portions 102a-c may be configured to connect to one another in any suitable manner. The mating surfaces 112 of the vessel portions 102a-c may not require the presence of a flange 111. For example, the vessel portions 102a-c may each comprise corresponding or complementary portions of a connecting mechanism such as a thread or a resilient clip, or the vessel portions 102a-c may be configured to connect to one another using a snap fit connection or a friction fit.

One of the mating surfaces 112 comprise a seal 116, as shown in FIG. 2B. In the embodiment shown, the seal 116 comprises an O-ring rubber seal, although any suitable seal material and/or seal structure may alternatively be used. The seal 116 may ensure that the connection between the vessel portions 102a-c is substantially fluid-tight to prevent leaks when the mating surfaces 112 are brought into contact with one another. In the embodiment shown, the seal 116 is set into a groove in the mating surface 112, although that is not essential. For example, the seal 116 may sit proud of the mating surface 112. The seal 116 may simply be sandwiched or compressed between the mating surfaces 112 of adjacent vessel portions 102a-c when the vessel portions 102a-c are attached to one another. Alternatively, the vessel portions 102a-c may be configured to attach to one another without a seal. Sufficient pressure may be applied by the one or more fasteners to secure the vessel portions 102a-c to one another in a substantially fluid-tight manner when the mating surfaces 112 are brought into contact with one another.

The mating surfaces 112 shown in FIGS. 2B and 2C comprise complementary engagement features 118. In the embodiment shown, the engagement features 118 comprise a plurality of raised areas or regions 118a (FIG. 2B) and a corresponding plurality of recessed areas or regions 118b (FIG. 2C). The raised areas 118a are configured to be received by the recessed areas 118b when the mating surfaces 112 of the respective vessel portions 102a-c are brought into contact with one another. That may further secure the vessel portions 102a-c to one another, by inhibiting or preventing rotation of the vessel portions 102a-c relative to one another when attached. The complementary engagement features 118 may also act to easily locate the respective vessel portions 102a-c in the correct position relative to one another when attaching the vessel portions 102a-c to one another. In the embodiment shown, four raised areas 118a and four recessed areas 118b are provided on the respective mating surfaces 112, although any number of raised areas 118a and corresponding recessed areas 118b may be provided. The raised areas 118a and the recessed areas 118b are disposed substantially symmetrically on the mating surfaces 112, with a raised area 118 or recessed area 118b provided approximately every 90° around the annular regions 112a of the mating surfaces 112, although the raised areas 118a and recessed areas 118b may be disposed at any suitable location on the mating surfaces 112. For example, the raised areas 118a and recessed areas 118b may be or comprise a single, substantially annular area or one or more arc-shaped areas. Alternatively, the mating surfaces 112 may not comprise complementary engagement features.

The respective mating surfaces 112 at either end of the central portion 102c comprise recessed areas 118b in the embodiment shown (as shown in FIG. 2C), whilst the mating surfaces 112 of the end portions 102a, 102b comprise raised areas 118a (as shown in FIG. 2B). That results in an axisymmetric vessel 102 that may allow either end portion 102a, 102b to be attached to either end of the central portion 102c. Alternatively, the respective mating surfaces at either end of the central portion 102c may comprised raised areas 118a, whilst the mating surfaces 112 of the end portions 102a, 102b may comprised recessed areas 118b. Alternatively, the central portion 102c may comprise raised areas 118a on the mating surface 112 at a first end of the central portion 102c and recessed areas 118b on the mating surface 112 at a second, opposing end of the central portion 102c. Each end of the central portion 102c may therefore be configured to attach to only one of the respective end portions 102a, 102b.

In the embodiment shown, the vessel 102 and the vessel portions 102a-c comprise or are manufactured from polyether ether ketone (PEEK). The mechanical and thermal properties of PEEK, together with its chemical resistance and being an electrical insulator, make it particularly suitable for use in a hybrid electrochemical and abrasive fluid polishing process. Alternatively, the vessel 102 and the vessel portions 102a-c may be manufactured from or comprise any suitable material such as acrylic, polytetrafluoroethylene (PTFE), polyvinylidene difluoride (PVDF) or a fibre reinforced plastic (FRP).

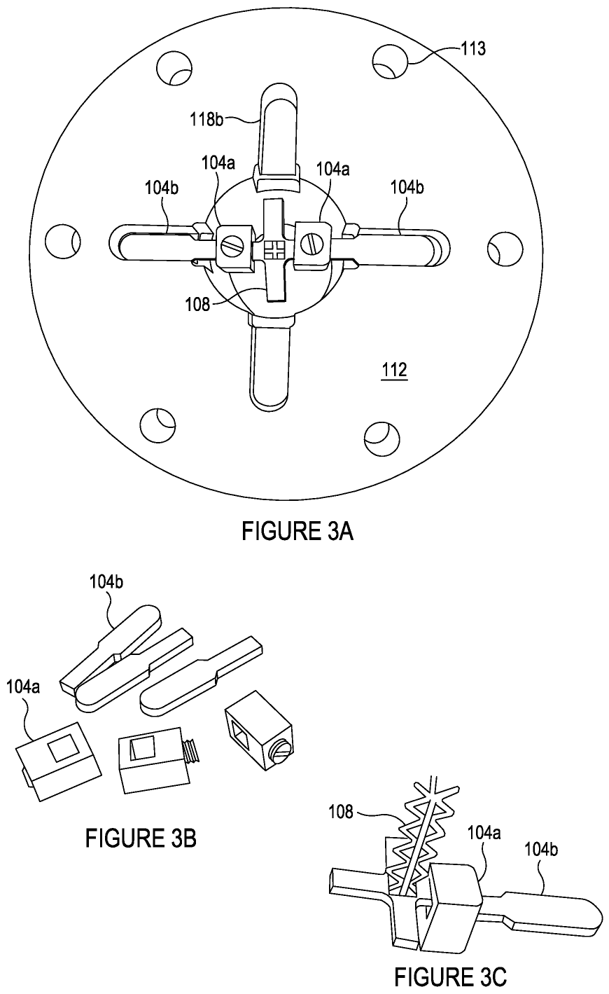

FIGS. 3A-C show a mount 104 of the apparatus 100 in greater detail. The mounts 104 are configured to releasably hold or secure a workpiece 108 (e.g., a part to be polished, as shown in FIGS. 3A and 3C) and/or a cathode 110 (not shown) in the vessel 102 between the inlet 103a and the outlet 103b. The mounts 104 are configured to be secured between the mating surfaces 112 of the vessel portions 102a-c when the vessel portions 102a-c are attached to one another to form the vessel 102. That may inhibit or prevent movement of the mounts 104 during use, enabling the mounts 104 to hold the workpiece 108 and/or the cathode 110 in a stable position when fluid is flowing through the vessel 102. Securing the mounts 104 between the vessel portions 102a-c also ensures that the workpiece 108 and/or the cathode 110 are held in the vessel 102 such that there is a substantially fixed distance between the workpiece 108 and the cathode 110 (e.g., approximately a length of the central portion 102c in the embodiment shown). That may allow a polishing process to be more easily controlled, because the distance between the workpiece 108 and/or the cathode 110 is known. That may also ensure that the workpiece 108 and the cathode 110 have difference circuit loops for electrochemical polishing to take place (discussed further below). In addition, securing the mounts 104 between the vessel portions 102a-c may enable the workpiece 108 and/or the cathode 110 to easily be placed or secured within a vessel 102 having a small chamber (for example, too small for an operator to manually reach inside the chamber of the vessel 102 to secure the workpiece 108 and/or the cathode 110).

In the embodiment shown, the mounts 104 are configured to be secured between the raised areas 118a and the complementary recessed areas 118b of adjacent mating surfaces 112. As shown in FIG. 3, at least a part of the mount 104 is configured to be received by a recessed area 118b on the mating surface 112, such that the mount 104 can be secured between the recessed area 118b and the corresponding raised area 118a of another mating surface 112 (shown schematically in FIG. 1). The mounts 104 may therefore be secured between the vessel portions 102a-c whilst still enabling the mating surfaces 112 to be brought into contact with one another to form a substantially fluid-tight seal when the vessel portions 102a-c are attached to one another. Alternatively, if the mating surfaces 112 do not comprise complementary engagement features 118, the mounts 104 may be secured directly between the mating surfaces 112. In such cases, a seal 116 (described above) may be required to ensure a substantially fluid-tight seal when the vessel portions 102a-c are attached to one another.

Each mount 104 comprises one or more connecting portions 104a and one or more projections 104b extending from the connecting portions 104a. In the embodiment shown, the mount 104 comprises a plurality of connecting portions 104a and a projection 104b extending from each connecting portion 104a. Alternatively, a mount 104 may comprise a single connecting portion 104a, and a single projection 104b or a plurality of projections 104b extending from the connecting portion 104a. Each connecting portion 104a is configured to physically connect to both a workpiece 108 (as shown in FIGS. 3A and 3C) or a cathode 110 and the projection(s) 104b. The connecting portions 104a comprises a threaded clamp in the embodiment shown, in which a part of the workpiece 108 and a part of the projection(s) 104b may be secured. Alternatively, any suitable releasable connection mechanism may be used (for example, a sprung clamp). In the embodiment shown, the connecting portions 104a and the projections 104b are separable from one another (as shown in FIG. 3B showing the mount 104 in a disassembled state), but the connecting portions 104a and the projections 104b may alternatively be or comprise a single, unitary structure.

The projections 104b are configured to be secured between the mating surfaces 112 of the vessel portions 102a-c. In the embodiment shown, each projection 104b is configured to be received between the complementary raised areas 118a and recessed areas 118b of the mating surfaces 112. The projections 104b are substantially planar, having a size and shape substantially corresponding to a size and shape of the recessed areas 118b. In the embodiment shown, the projections 104b therefore have a substantially elongate structure. Alternatively, if the recessed area 118b is or comprises, for example, a single, substantially annular area or one or more arc-shaped areas, the projection(s) 104b may have a corresponding annular shape or arc shape. The recessed areas 118b and the projections 104b having substantially similar shapes may further secure the mount 104 when the vessel portions 102a-c are attached to one another, by substantially inhibiting or preventing movement of the mount 104 in a plane of the projections 104b.

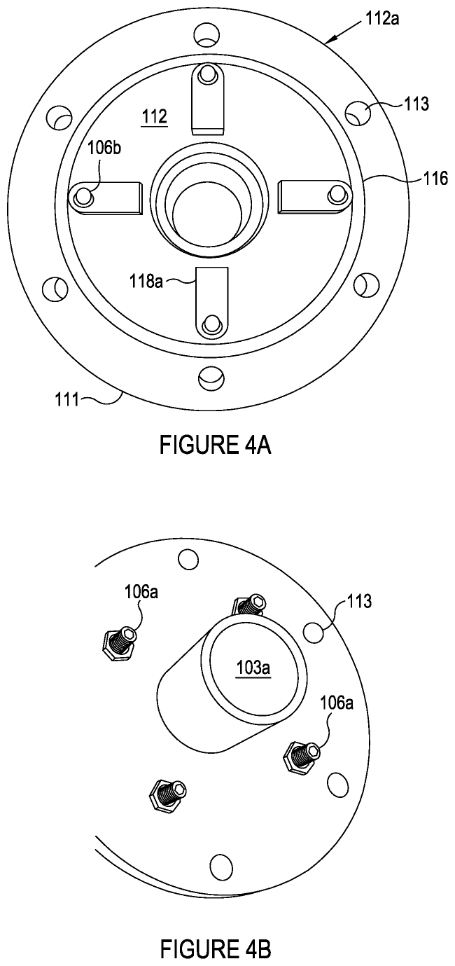

FIGS. 4A and 4B show a connector 106 of the apparatus 100 in more detail. The connectors 106 are configured to connect the workpiece 108 and the cathode 110 to an electrical power supply, for example an electrical power supply external to the apparatus 100. The connectors 106 comprise a conductive material, for example copper, although any suitable conductive material may be used instead. At least a part of each connector 106 extends externally from the vessel 102, as shown in FIG. 4B. In the embodiment shown, that external portion 106a extends from a rear surface of the flange 111 substantially opposite the mating surface 112, although the external portion 106a may extend from any external surface of the vessel 102, for example an external surface of the flange 111 that is not a mating surface 112. The external portion 106a of the connector 106 therefore provides an easily accessible structure to which an electrical power supply can be connected. In the embodiment shown, the connector 106 is fixed to the flange 111 of the vessel portion 102a-c using a nut that screws onto a thread disposed on the external portion 106a.

The connector 106 extends from a point external to the vessel 102, through the mating portion or flange 111 of the vessel portion 102a-c, to the mating surface 112 in the embodiment shown. At least a part of the connector 106 extends away from the mating surface 112, as shown in FIG. 4A. That internal portion 106b of the connector 106 is configured to form an electrical contact with the mount 104 when the mount 104 is secured between the mating surfaces 112 of attached vessel portions 102a-c. The connector 106 is therefore configured to connect the workpiece 108 to an electrical power supply indirectly via the mount 104. In the embodiment shown, the mount 104 comprises an electrically conductive material that is used to form an electrical contact between the internal portion 106b of the connector 106 and the workpiece 108. For example, one or more projections 104b of the mount 104 may be or comprise an electrically conductive material. The connecting portion 104a may be configured to secure the projection 104b to the workpiece 108 to form an electrical contact between the projection 104b and the workpiece 108. For example, the connecting portion 104a may clamp the projection 104b of the mount 104 and the workpiece 108 together. The connecting portion 104a may be made from or comprise an electrically insulating material, although that is not essential.

Using the connector 106 to connect the workpiece 108 to an electrical power supply indirectly via a mount 104 secured between the mating surfaces 112 of attached vessel portions 102a-c, as described above, may provide a convenient way to form an electrical connection with the workpiece 108. Doing so makes use of an existing structure (the mount 104) which protrudes into the internal space enclosed by the chamber and is in contact with the workpiece 108. In that way, the connector 106 can form an electrical connection with the workpiece 108 during operation of the apparatus 100 without physically entering the internal space enclosed by the chamber. That may reduce the number of parts of the apparatus 100 which are exposed to potentially harsh environmental conditions during a polishing process (for example, a hybrid polishing process). That may also reduce a number of potential leak points of the apparatus 100, by using a single entry route into the internal space of the chamber of the vessel 102 for multiple purposes (e.g., to form both a physical and an electrical connection to the workpiece 108). Securing the workpiece 108 and the cathode 110 between different pairs of vessel portions 102a-c and providing separate connectors 106 for each of the workpiece 108 and the cathode 110 also ensures that the workpiece 108 and the cathode 110 have different circuit loops for electrochemical polishing to take place.

The internal portion 106b of the connector 106 is or comprises a resilient structure or material (for example, a spring) that allows the internal portion 106b of the connector 106 to be compressed when brought into contact with the mount 104. That may prevent damage to the internal portion 106b of the connector 106 when compressed between the mating surface 112 and the mount 104. That may also allow an electrical contact to be formed whilst still enabling a substantially fluid-tight seal to be formed between the mating surfaces 112 when the vessel portions 102a-c are attached to one another. Alternatively, the internal portion 106b of the connector 106 may not comprise a resilient structure or material.

In the embodiment shown, the connectors 106 are spatially arranged on the flange 111 to substantially mirror the spatial arrangement of the raised areas 118a on the mating surface 112. The internal portions 106b of the connectors 106 are therefore located on and extend from the raised areas 118a of the mating surface (as shown in FIG. 4A). Unless the raised areas 118a are aligned with the corresponding recessed areas 118b, the mating surfaces 112 may not be brought into contact one another to attach the vessel portions 102a-c. Locating the internal portions 106b of the connectors 106 on the raised areas 118a may therefore automatically ensure that the internal portions 106b of the connectors 106 are positioned to form an electrical contact with the projections 104b of the mount 104 that are received in the corresponding recessed areas 118b of the adjoining mating surface 112. Alternatively, if the mating surfaces 112 do not comprise complementary engagement features, the mount 104 may be secured between substantially any part of the mating surfaces 112, and the connector(s) 106 may be located at substantially any point on the flange 111.

Alternatively, the mounts 104 may not be configured to be secured between the mating surfaces 112 of the vessel portions 102a-c. The vessel 102 may be or comprise a single, unitary structure. The mounts 104 may alternatively be configured to be attached to an internal surface of the vessel 102, for example an internal surface of a substantially enclosed chamber formed by the vessel. An internal surface of the vessel 102 and the mounts 104 may comprise complementary attachment features. For example, the mounts 104 may be or comprise a structure configured to connect to the workpiece 108 and comprising a recess that is configured to receive a boss located on an internal surface of the vessel 102 to secure the mount 104 to the vessel 102. Alternatively, the mounts 104 may be or comprise a structure configured to connect to the workpiece 108 and comprising a threaded portion that is configured to engage with a complementary threaded portion on an internal surface of the vessel 102. The connector(s) 106 may be configured to extend through a wall of the vessel 102 and either contact or form the attachment features provided on the internal surface of the vessel to which the mounts 104 attach. The mount 104 and the attachment feature may therefore be or comprise an electrically conductive material.

Alternatively, if the vessel 102 comprises an open-topped structure, the mounts 104 may not physically interact with the vessel 102. For example, the mounts 104 may secure the workpiece 108 and the cathode 110 in the vessel 102, between the inlet 103a and the outlet 103b, by suspending the workpiece 108 and the cathode in the vessel 102 from above.

Alternatively, the connector(s) 106 may not be configured to functionally interact with the mounts 104, and may instead be or comprise one or more independent structures that form an electrical connection directly with the workpiece 108 or the cathode 110 (for example, independent of the mounts 104). The connector(s) 106 may have a separate path into an internal space of the vessel 102. For example, the connector(s) 106 may be configured to pass through an aperture provided in a wall of the vessel 102 and form a direct electrical contact with the workpiece 108 or the cathode 110.

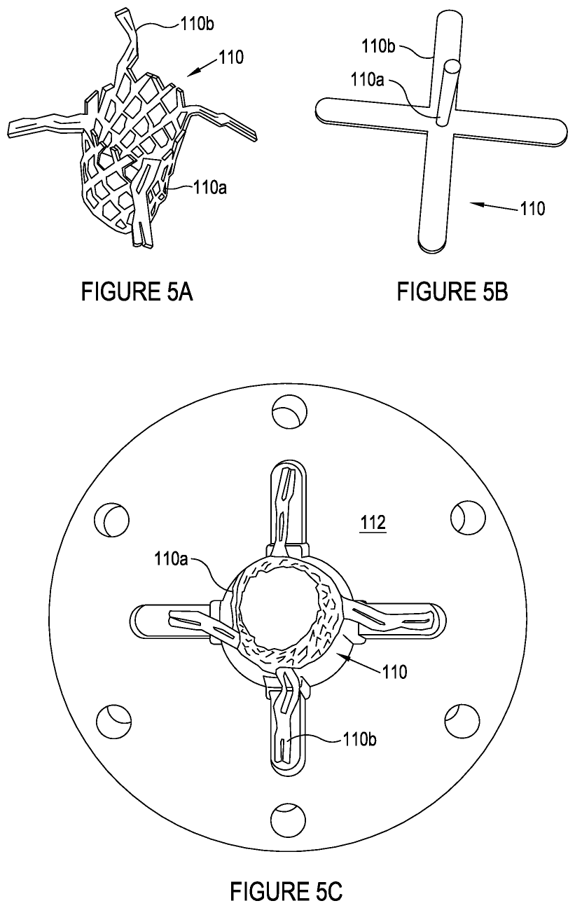

FIGS. 5A-C show examples of a cathode 110 for use with the apparatus 100 in greater detail. The cathodes 110 are made from or comprise an electrically conductive material. The cathodes 110 are configured to be secured between the mating surfaces 112 of the vessel portions 102a-c in order to be held in the vessel 102 when the vessel portions 102a-c are attached to one another. The cathodes 110 are configured to be secured between the mating surfaces 112 of the vessel portions 102a-c without a mount 104. Each of the cathodes 110 shown in FIGS. 5A and 5B comprises a cathode body 110a and one or more projections 110b extending from the cathode body 110a. In the embodiments shown, the cathodes 110 comprise four projections 110b extending from the cathode body 110a, but any number of projections 110b may be used (for example, one, two, three, five, six etc.). The projections 110b are configured to be secured between the mating surfaces 112 of the vessel portions 102a-c, substantially as described above for the projections 104b of the mounts 104. By securing the projections 110b between the mating surfaces 112, the cathode body 110a may be securely held in the vessel 102. In the embodiments shown, the projections 110b are configured to be received between the complementary raised areas 118a and recessed areas 118b of the mating surfaces 112, as shown in FIG. 5C and substantially as described above for the projections 104b of the mounts 104 (although that is not essential). The projections 110b may therefore comprise a size and/or shape as the recessed areas 118b of the mating surface 112, although that is not essential. The connector(s) 106 may contact the cathodes 110 by contacting the projections 110b of the cathodes 110 to form an electrical connection, substantially as described above for the projections 104b of the mounts 104.

Alternatively, the cathode 110 may not comprise any projections 110b. The cathode 110 may substantially comprise a cathode body 110a only and may be secured in the vessel 102 by one or more mounts 104, substantially as described above.

The cathode body 110a of the cathodes 110 in the embodiments shown are configured such that, when secured in the vessel 102, the cathode body 110a partially spatially overlaps with at least a part of a workpiece 108 within the vessel 102 (although without physically contacting the workpiece 108, to enable electrochemical polishing to take place). The cathode body 110a may partially spatially overlap with at least a part of a workpiece 108 within the vessel 102. However, that is not essential.

FIG. 5A shows a cathode body 110a comprising a lattice or mesh structure forming a substantially hollow shape. The cathode body 110a is configured to spatially overlap with a workpiece 108 by substantially enveloping the workpiece 108 within the hollow shape of the cathode body 110a. The cathode body 110a is configured to allow the workpiece 108 to be received within the hollow shape. The lattice or mesh structure of the cathode body 110a may be particularly beneficial for electrochemical polishing of a workpiece 108 also having a lattice or mesh structure, but may also be used for a workpiece 108 that does not comprise an internal structure or channel. Alternatively, the cathode body 110a may have a substantially hollow shape having substantially continuous walls rather than a lattice or mesh structure. In the embodiment shown, the hollow shape defined by the cathode body 110a is open at both ends, but alternatively the hollow shape of the cathode body 110a may be open at only one end.

FIG. 5B shows an alternative cathode body 110a comprising a rod or wire structure. The cathode body 110a is configured to spatially overlap with a workpiece 108 by being received within an internal space or channel of the workpiece 108. A diameter or cross-sectional area of the rod structure of the cathode body 110a may depend on a size (e.g., radius) of the internal channel(s) of the workpiece 108. For example, a rod structure of a cathode body 110a configured for use with a workpiece 108 comprising an internal channel having a first radius of curvature r₁ may have a greater diameter or cross-sectional width than a rod structure of a cathode body 110a configured for use with a workpiece 108 comprising an internal channel having a second radius of curvature r₂ where r₁>r₂. In the embodiment shown, the cathode body 110a comprises a substantially cylindrical wire structure, although a rod or wire structure having any suitable cross-sectional shape may be used. For example, a square or triangular rod or wire structure may be used instead.

The structure of the cathode body 110a of the cathode may therefore be selected dependent upon a structure of the part to be polished. A cathode body 110a of a cathode 110 may comprise both a substantially hollow shape configured to substantially envelop a workpiece 108 and a rod or wire structure configured be received within an internal channel of the workpiece 108. Alternatively, the cathode body 110a of the cathode 110 may not be configured to at least partially spatially overlap with (for example, envelop or be received within) the workpiece 108 within the vessel 102. The cathode body 110a may have any suitable shape or configuration. Hybrid polishing (for example, hybrid electrochemical and abrasive fluid polishing) may be carried out with the cathode 110 and the workpiece 108 both secured within the vessel 102, without overlapping with one another (for example, spaced apart from one another, such as at a substantially fixed distance from one another).

In the embodiments shown, the cathode 110 comprises or is made from titanium. Titanium cathodes are usually used for polishing stainless steel parts. Alternatively, the cathode 110 may be or comprise a different material such as platinum or stainless steel, for example to polish parts made from Ti-6Al-4V (Ti64).

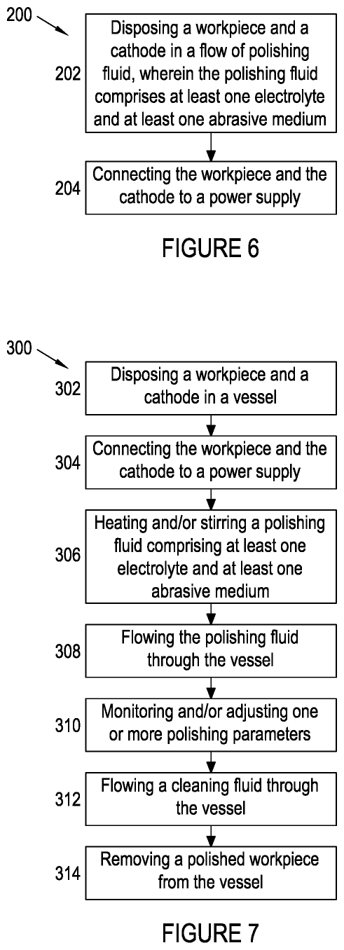

FIG. 6 shows a method 200 of performing hybrid electrochemical and abrasive fluid polishing, in accordance with an embodiment of the invention. The method 200 comprises disposing a workpiece and a cathode in a flow of polishing fluid at step 202. The polishing fluid comprises at least one electrolyte and at least one abrasive medium. The method 200 also comprises connecting the workpiece and the cathode to a power supply at step 204.

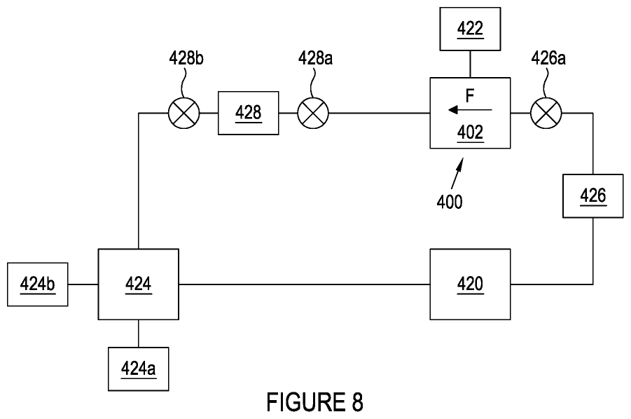

FIG. 7 shows a method 300 of performing hybrid electrochemical and abrasive fluid polishing, in line with the method 200 set out above. The method 300 may be carried out using, and is described with respect to, a system for hybrid electrochemical and abrasive fluid polishing as shown in FIG. 8, in accordance with an embodiment of the invention.

The system comprises a polishing apparatus 400. In the embodiment shown, the polishing apparatus 400 is substantially similar to the apparatus 100 described above with respect to FIGS. 1 to 4, with corresponding features indicated by like reference numerals. However, any suitable polishing apparatus 400 that allows a workpiece and a cathode to be disposed in a flow of fluid and connected to an electrical power supply may be used.
Step 302 of the method 300 comprises disposing a workpiece and a cathode in a vessel. The polishing apparatus 400 comprises a vessel 402 in which a workpiece and a cathode can be secured. The vessel 402 comprises an inlet and an outlet allowing a fluid to flow through the vessel 402.
Step 304 of the method 300 comprises connecting the workpiece and the cathode to a power supply. The system also comprises an electrochemical workstation 422. The electrochemical workstation 422 acts as an electrical power supply to which the workpiece and the cathode are electrically connected via one or more connectors (not shown) of the polishing apparatus 400, as described above. That arrangement allows hybrid electrochemical and abrasive fluid polishing to be performed on the workpiece and the cathode in the vessel 402.
Step 306 of the method 300 optionally comprises heating and/or stirring a polishing fluid. The polishing fluid comprises at least one electrolyte and at least one abrasive medium, allowing the polishing fluid to perform hybrid electrochemical and abrasive fluid polishing on the workpiece held in the vessel 402, as described above. The system 400 comprises a storage tank 424 in which the polishing fluid may be stirred and or heated. In the embodiment shown, the system 400 comprises a heating device 424a configured to heat the polishing fluid in the storage tank 424. The heating device 424a may be configured to heat the polishing fluid to a temperature of between substantially 0° C. and substantially 120° C., and optionally between substantially 20° C. and substantially 90° C. The heating device 424a may enable the polishing fluid to be held at a substantially constant desired temperature during the hybrid electrochemical and abrasive fluid polishing process. In the embodiment shown, the system 400 also comprises a stirring device 424b configured to mix the polishing fluid in the storage tank 424. The stirring device 424b may ensure a substantially homogeneous distribution of the at least one electrolyte and the at least one abrasive medium in the polishing fluid. Alternatively, the method 300 may not comprise step 306. The system 400 may not comprise a heating device, and/or the system 400 may not comprise a stirring device.
Step 308 of the method 300 comprises flowing the polishing fluid through the vessel. The system further comprises at least one pump 420. The pump 420 is configured to deliver the polishing fluid to the vessel 402 of the polishing apparatus 400, to provide a flow of polishing fluid through the vessel 402. The flow direction of the polishing fluid through the vessel 402 is depicted by the arrow F in FIG. 8. In the embodiment shown, the pump 420 is or comprises a peristaltic pump, although any suitable pump may be used. The pump 420 may be controllable to deliver variable flow, for example up to substantially 30 L·min⁻¹, and preferably between substantially 3 L·min⁻¹ and substantially 22 L·min⁻¹, although the pump 420 may be configured to deliver any suitable flow.
Step 310 of the method 300 comprises monitoring and/or controlling or adjusting one or more polishing parameters during the hybrid polishing process. In the embodiment shown, step 310 comprises monitoring and adjusting one or more of a polishing fluid pressure, a polishing fluid temperature, a polishing fluid flow rate, an electric current and/or current density, and an electric potential. Step 310 may comprise adjusting one or more of the polishing parameters based on the monitoring of the one or more polishing parameters.

In the embodiment shown, the system further comprises a pressure gauge 426. The pressure gauge 426 is configured to monitor a pressure of the polishing fluid from the pump 420 prior to the polishing fluid entering the vessel 402. The system also comprises a valve 426a configured to regulate or control a pressure of the polishing fluid entering the vessel 402. In the embodiment shown, the valve 426a is a needle valve, although any suitable valve type may be used. In the embodiment shown, the valve 426a regulates a pressure of the polishing fluid to provide a desired polishing fluid pressure of up to 0.5 MPa. Alternatively, any suitable polishing fluid pressure may be used instead, which may be determined, for example, by a maximum pressure that the pump 420 or any pipes connecting the pump 420 to the vessel 402 may be configured to tolerate. In the embodiment shown, a distance between pump 420 and the vessel 402 is short enough (for example, substantially 1 m or less, and preferably approximately 30 cm) that the pressure from the pump 420 and at the vessel 402 may be considered approximately equal. The pressure gauge 426 may therefore be configured to measure both a pressure of both polishing fluid delivered from the pump 420 and polishing fluid to be delivered to the vessel 402. Similarly, the valve 426a may therefore be configured to control a pressure of both polishing fluid delivered from the pump 420 and polishing fluid entering the vessel 402. However, that arrangement is not essential. Alternatively, the system may not comprise a pressure gauge or a valve, and the polishing fluid may be delivered directly into the vessel 402 from the pump 420.

The system also comprises a flow meter 428. The flow meter 428 is configured to measure a flow velocity. The flow meter 428 may also be configured to measure a fluid mass and/or a fluid density. The flow meter 428 is further configured to determine a flow velocity in the vessel 402 using the measured flow velocity and the internal cross-sectional dimensions (e.g., diameter, width, height) of the vessel 402. The pump 420 may be configured to provide a flow that provides a flow rate of up to substantially 20 m·s⁻¹ through the vessel 402, although any suitable flow rate may be used. The pump 420 may be controlled to vary a flow delivered by the pump 420 based on the flow velocity determined by the flow meter 428, to provide a desired flow rate within the vessel 402.

In the embodiment shown, the flow meter 428 is located (in respect of the flow of fluid through the system) after the polishing apparatus 400. That may separate the flow meter 428 from the pump 420 by a sufficient distance to ensure sufficient accuracy of measurements made by the flow meter 428. Otherwise, vibrations caused by the pump 420 may interfere with measurements made by the flow meter 428. In the embodiment shown, the flow meter 428 is located (in respect of the flow of fluid through the system), between a first valve 428a and a second valve 428b. The first and second valves 428a, 428b may enable calibration and/or modulation of the zero point of the flow meter 428. The first and second valves 428a, 428b are ball valves in the embodiment shown, although any suitable valves may be used.

The system also comprises a temperature sensor (not shown), such as a thermometer, configured to monitor a temperature of the polishing fluid. The temperature sensor may be located in the storage tank 424, in the vessel 402, or in the flow meter 428, although the temperature sensor may be located at any suitable point in the system. The operation of the heating device 424a may be controlled based on the measurement made by the temperature sensor, to ensure the polishing fluid remains at a desired temperature.

The electrochemical workstation 422 may also be configured to monitor and/or control or adjust polishing parameters such as a polishing current or current density and/or a polishing potential. For example, by measuring a polishing current, a current density can be calculated automatically using a known input area of the workpiece. In the embodiment shown, the electrochemical workstation 422 is configured to provide a polishing current of up to 2 A, and a polishing potential up to 50V, although alternatively the electrochemical workstation 422 may be configured to provide any suitable magnitude of polishing current and/or polishing potential.
Step 310 may comprise controlling a plurality of polishing parameters, for example substantially simultaneously. For example, a polishing fluid temperature may influence polishing current. In general, increasing a polishing fluid temperature will increase polishing current. However, if the polishing current increases too much, a rate of material removal from the workpiece may be too high, resulting in excessive material removal from a surface of the workpiece, over-etching and material waste. Each polishing parameter may therefore coordinate with (and/or be controlled together with) one or more other polishing parameters to achieve efficient, effective polishing. The system may comprise one or more controllers configured to control one or more of the polishing parameters. The controller(s) may be integral to the other components of the system (for example, the electrochemical workstation 422, the flow meter 428 etc.), or may be separate devices configured to be in electrical communication with the other components of the system.

In the embodiment shown, the storage tank 424 is configured to receive the polishing fluid from the vessel 402. The storage tank 424, the pump 420 and the vessel 402 may therefore form a substantially closed loop around which the polishing fluid is circulated, although that is not essential.
Step 312 of the method 300 optionally comprises flowing a cleaning fluid through the vessel, after the workpiece has been polished using the polishing fluid. The pump 420 may be configured to drive a cleaning fluid such as water (e.g., deionized water) through the vessel 402 to clean the workpiece following the hybrid electrochemical and abrasive fluid polishing. The system may comprise an additional reservoir for containing the cleaning fluid. The additional reservoir may be placed in fluid communication with the pump 420 in place of the storage tank 424 containing the polishing fluid. Alternatively, the polishing fluid may be removed from the storage tank 424 and replaced by the cleaning fluid.
Step 314 of the method 300 comprises removing a polished workpiece from the vessel.

The polishing fluid used in the methods described above comprises an electrolyte comprising a weak acid. Preferably, the electrolyte comprises a mixture of a weak acid and a viscous component, and the polishing fluid further comprises at least one abrasive medium. In some embodiments, the electrolyte comprises a mixture of between substantially 20% and substantially 80% weak acid by volume, between substantially 5% and substantially 50% viscous component by volume, and water. In the embodiments shown, the weak acid comprises phosphoric acid (for example, 85%+ aqueous solution phosphoric acid), the viscous component comprises glycerine and the water comprises deionised water, although that is not essential. It will be appreciated that the concentration of weak acid in the electrolyte depends on the initial concentration of the weak acid itself and the proportion of weak acid in the electrolyte. Alternatively or additionally, a different weak acid may be used (for example, one or more of citric acid, acetic acid such as glacial acetic acid), and/or a different viscous component may be used (for example, one or more of glycol, methanol, butanol, isopropanol or methanol). In the embodiment shown, the at least one abrasive medium comprises SiC particles. The SiC particles are up to 300 μm in size (for example, diameter) and up to 50% by mass of the polishing fluid, although that is not essential. Alternatively, an additional or different abrasive medium (for example, B₄C, BN such as cubic BN, Al₂O₃ or plastic) may be used, having a different particle size and/or in a different amount (such as % by mass).

Examples of electrolyte compositions are shown in Table 1 below. In the methods described above, the electrolyte composition of example 1 is used in the polishing fluid, although any suitable composition (such as either of examples 2 and 3) may be used instead.

TABLE 1
Table showing example electrolyte compositions for use
in chemical and/or electrochemical processing such as
hybrid electrochemical and abrasive fluid polishing.

| | | Viscous | |
|---|---|---|---|
| | Weak Acid | component | Water |
| Example | (% volume) | (% volume) | (% volume) |
| 1 | Phosphoric acid 85%+ (30) | Glycerine (10) | 60 |
| 2 | Phosphoric acid 85%+ (45) | Glycerine (15) | 40 |
| 3 | Phosphoric acid 85%+ (60) | Glycerine (20) | 20 |

The electrolyte compositions described above, including those shown in Table 1, may alternatively be used without an abrasive medium for electrochemical processing.

From reading the present disclosure, other variations and modifications will be apparent to the skilled person. Such variations and modifications may involve equivalent and other features which are already known in the art of surface preparation and polishing, and which may be used instead of, or in addition to, features already described herein.

For the sake of completeness, it is also stated that the term “comprising” does not exclude other elements or steps, the term “a” or “an” does not exclude a plurality, a single processor or other unit may fulfil the functions of several means recited in the claims and any reference signs in the claims shall not be construed as limiting the scope of the claims.

1. A method of performing hybrid electrochemical and abrasive fluid polishing, the method comprising:
disposing a workpiece to be polished and a cathode in a flow of polishing fluid, wherein the polishing fluid comprises at least one electrolyte and at least one abrasive medium; and
connecting the workpiece and the cathode to an electrical power supply.

2. The method of claim 1, wherein the electrolyte comprises an environmentally friendly electrolyte.

3. The method of claim 1, wherein the electrolyte comprises a weak acid, and optionally wherein the electrolyte comprises phosphoric acid.

4. The method of claim 3, wherein the electrolyte comprises a mixture of a weak acid and a viscous component, and optionally wherein the viscous component comprises one or more of glycerine, glycol and methanol; and, optionally or preferably, wherein the electrolyte comprises:
between substantially 20% and substantially 80% weak acid by volume; and
between substantially 5% and substantially 50% viscous component by volume.

5. (canceled)

6. The method of claim 1, wherein the at least one abrasive medium comprises at least one of:
i) ceramic particles, and optionally wherein the ceramic particles comprise at least one of SiC particles, B₄C particles and Al₂O₃ particles; and
ii) plastic particles.

7. The method of claim 1, wherein disposing the workpiece and the cathode in the flow of polishing fluid comprises locating the workpiece and the cathode in a vessel, the vessel comprising an inlet and an outlet to allow the fluid to flow through the vessel, and optionally wherein the vessel comprises a hollow chamber.

8. The method of claim 1, further comprising disposing the workpiece in a cleaning fluid, and optionally disposing the workpiece in a flow of cleaning fluid, and further optionally wherein the cleaning fluid is or comprises deionized water.

9. The method of claim 1, further comprising monitoring one or more polishing parameters, and optionally wherein the one or more polishing parameters comprise one or more of a polishing fluid pressure, a polishing fluid flow rate, a polishing fluid temperature, a current and/or a current density, and an electric potential; and, optionally or preferably, further comprising controlling or adjusting at least one of the one or more polishing parameters, and optionally based on the monitoring.

10. (canceled)

11. An apparatus for hybrid electrochemical and abrasive fluid polishing, the apparatus comprising:
a vessel comprising an inlet and an outlet to allow a flow of fluid through the vessel;
one or more mounts configured to hold a workpiece to be polished in the vessel between the inlet and the outlet; and
one or more connectors configured to connect the workpiece and a cathode to an electrical power supply.

12. The apparatus of claim 11, wherein the vessel comprises a hollow chamber substantially enclosing a space between the inlet and the outlet, and optionally wherein the chamber comprises a bore or conduit between the inlet and the outlet.

13. The apparatus of claim 11, wherein the vessel comprises a plurality of releasably attachable vessel portions.

14. The apparatus of claim 13, wherein the vessel comprises a central portion and two end portions, wherein each end portion is configured to attach to a separate end of the central portion

15. The apparatus of claim 13, where each vessel portion comprises at least one mating surface configured to engage with a corresponding mating surface of another vessel portion.

16. The apparatus of claim 15, wherein corresponding mating surfaces comprise complementary engagement features, and optionally wherein one of the mating surfaces comprises at least one raised area and the other mating surface comprises at least one recessed area; or
wherein the one or more mounts and/or the cathode are configured to be secured between the mating surfaces of adjacent vessel portions.

17. The apparatus of claim 11, wherein one or more of the mounts are configured to hold a cathode in the vessel between the inlet and the outlet.

18. (canceled)

19. The apparatus of claim 17, comprising a first mount configured to hold the workpiece and a second mount configured to hold the cathode, wherein the first mount and the second mount are configured to be secured between the mating surfaces of different vessel portions.

20. The apparatus of claim 11, wherein the one or more mounts comprise a conductive material, and the one or more connectors are configured to connect the workpiece and the cathode to a power supply via the one or more mounts; or wherein the vessel comprises polyether ether ketone, PEEK.

21. (canceled)

22. A fluid for electrochemical polishing, the fluid comprising a mixture of a weak acid and a viscous component.

23. The fluid of claim 22, wherein:
i) the weak acid is or comprises phosphoric acid; and
ii) the viscous component comprises one or more of glycerine, glycol and methanol.

24. The fluid of claim 22, wherein the fluid comprises:
i) between substantially 20% and substantially 80% of weak acid by volume; and
ii) between substantially 5% and substantially 50% of viscous component by volume; or, wherein the fluid further comprises at least one abrasive medium.

25. (canceled)
